(19) United States
(12) Patent Application Publication
(10) Pub. No.: US 2013/0300458 A1
(43) Pub. Date: Nov. 14, 2013

(54) Clock Signal Synchronization Circuit

(71) Applicants: Thomas le Huche, Grenoble (FR); Sylvain Engels, Meylan (FR)

(72) Inventors: Thomas le Huche, Grenoble (FR); Sylvain Engels, Meylan (FR)

(73) Assignee: STMICROELECTRONICS SA, Montrouge (FR)

(21) Appl. No.: 13/616,276

(22) Filed: Sep. 14, 2012

(30) Foreign Application Priority Data
May 11, 2012 (FR) 1254319

(51) Int. Cl. H03L 7/00; H03K 5/22

(52) U.S. Cl. 327/22; 327/153

(57) ABSTRACT

A circuit for detecting a time skew, including: at least two comparators; a first set of paths respectively connecting a first source of a first signal to said comparators; and a second set of paths respectively connecting a second source of a second signal to said comparators, each comparator detecting a possible skew between said first and second signals.

This application claims priority to French Patent Application No. 1254319, which was filed May 11, 2012 and is incorporated herein by reference.

### TECHNICAL FIELD

The present disclosure relates to the field of clock signal synchronization systems and more specifically to the measurement of the delay of clock signals between different nodes of a circuit (generally called clock skew) and the correction of this delay (generally called de-skew). The present disclosure relates to such systems, be they implemented when the circuit is being tested or during operating phases of this circuit.

### BACKGROUND

Generally, the clock signal of a circuit comprising several functions is generated by a single source, and then distributed to the other functions by means of a clock signal distribution tree, or clock tree. The clock signal may asynchronously reach the input points of the functions.

The physical dispersion of circuit characteristics on manufacturing and the layout imbalance of clock trees are the main contributors to the static skew of clock signals.

Voltage variations in the circuit, temperature variation from one point to the other of the circuit and phase jitter of the signal source are the main contributors to the dynamic skew of clock signals.

Such skews adversely affect the desired increase of the circuit operating frequency by forcing all the functions to wait for the arrival of the most delayed clock signal.

It is generally known to decrease the static skew by drawing a clock tree with a uniform layout. Among such layouts, the H-tree, according to a layout with uniform non-shorted buffers, and the clock mesh, according to a layout with uniform shorted buffers, are generally preferred.

A disadvantage of a uniform layout is that is does not compensate for the physical dispersion of circuit characteristics on manufacturing.

Another disadvantage of a mesh layout is its high power consumption. The mesh layout is achieved by means of metal strips. The resistivity specific to such strips induces variations in the clock signal propagation between nodes. Accordingly, short-circuits affect each of the nodes where such variations occur, thus resulting in high additional power consumption. Further, the self-capacitance of the strips also increases the power consumption. This makes it necessary to increase the buffer power to keep the clock signal frequency.

A disadvantage common to the two layouts is that they impose additional constraints with respect to automatic clock tree routing tools, which constraints are sometimes incompatible with the operation of these tools.

Another disadvantage is that the dynamic skew is not decreased.

Circuits for de-skewing the clock between different circuit nodes generally measure and compensate for this skew by means of programmable delay lines. The skew measurement may be tainted with error due to the length of the metal strips connecting the input nodes of the functions to the skew measurement component. This error mainly depends on the circuit size, on the distance of the leaves of the clock tree, on the clock signal frequency, and on the variability of the manufacturing method.

### SUMMARY OF THE INVENTION

These and other problems are generally solved or circumvented, and technical advantages are generally achieved, by preferred embodiments of the present invention, one of which provides for a circuit for detecting a time skew. The circuit includes at least two comparators. The circuit further includes a first set of paths respectively connecting a first source of a first signal to the comparators, and a second set of paths respectively connecting a second source of a second signal to the comparators. Each comparator detects a possible skew between said first and second signals.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows, in the form of a block diagram, an embodiment of a clock signal calibration system.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

It is difficult to predict the static and dynamic skew between clock signals during circuit design steps. A system for measuring and correcting the skew of clock signals between different nodes of a circuit enables one to handle static and dynamic skews along the product lifetime.

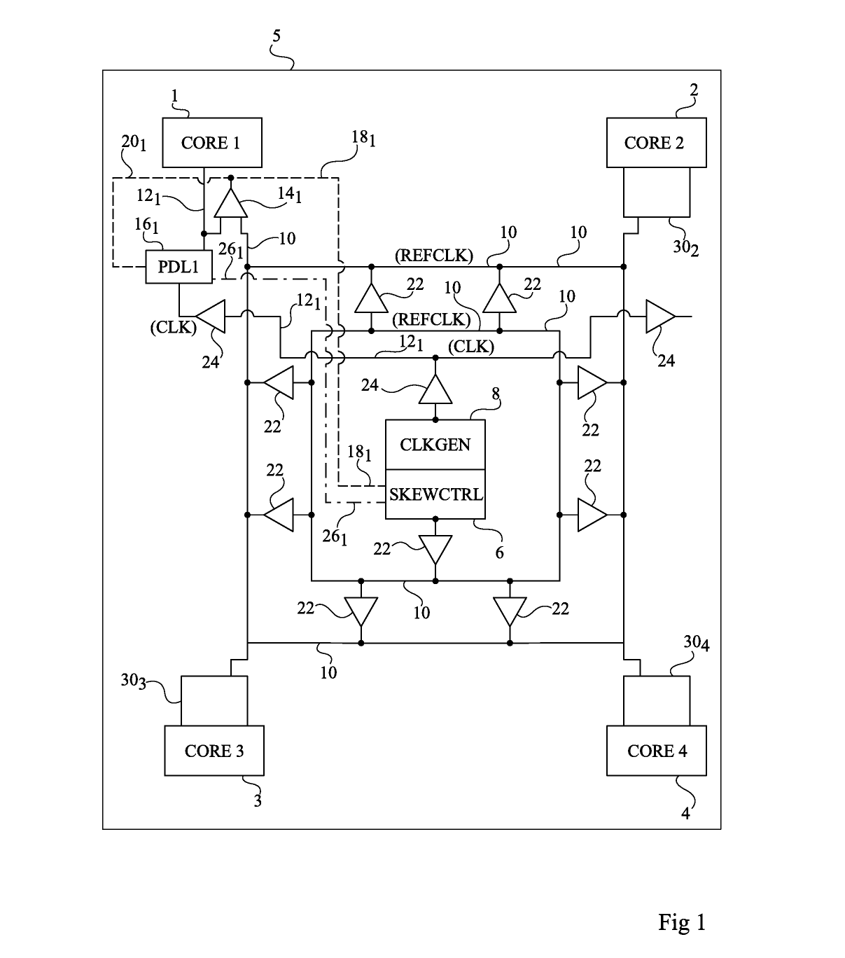

FIG. 1 describes an embodiment of such a system. A circuit 5 for example comprises four electronic functions 1 (CORE1), 2 (CORE2), 3 (CORE3), and 4 (CORE4) intended to receive a same clock signal and to be synchronized.

A circuit 6 (SKEWCTRL) generates a reference clock signal REFCLK. A clock tree 10 provides, by layout, an identical time distribution of signal REFCLK of circuit 6 towards functions 1 to 4. If necessary, tree 10 comprises amplifiers 22 (generally called buffers), compensating for variations of the signal excursion along the paths. Such amplifiers must be placed with an identical number on each of the paths between circuit 6 and each function. Tree 10 may also be any other tree which, by construction, provides an identical time distribution of signal REFCLK.

A circuit 8 (CLKGEN) generates a useful clock signal CLK. Signal CLK follows paths 12₁, 12₂, 12₃, 12₄ (only path 12₁ is shown, for clarify) of a clock tree 12 towards the functions CORE1 CORE2, CORE3, CORE4, respectively. If necessary, tree 12 also comprises amplifiers 24, similar to amplifiers 22.

In the example of function 1, path 12₁ conveys signal CLK between circuit 8 and function 1 (also referred to as CORE1).

Signal CLK crosses a programmable delay line 161 (PDL1). A comparator 141 has its respective inputs connected to path 12₁ and to tree 10.

Comparator 14₁ is arranged as close as possible to function 1. This comparator measures the time skew between signals CLK and REFCLK on arrival at function 1. This skew information (output of comparator 14₁) is transmitted to circuit 6 via a connection 18₁. Circuit 6 then transmits a control signal proportional to the time skew via a connection 261, towards delay line 16₁, thus shifting a signal CLK present at this time on path 12₁. This skewed signal is transmitted to function 1 and to comparator 14₁.

In other words, a regulation loop detects the skew between signal CLK transmitted to function 1 and signal REFCLK, to de-skew, if necessary, future periods of signal CLK, which will in turn be compared with future periods of signal REFCLK for a de-skewing, if necessary.

As a variation, comparator 14₁ characterizes the skew by data of “advanced” or “delayed” type, and then transmits said data to function 6 over connection 18₁. Function 6 then transmits to delay line 16₁ an instruction of delay or advance by a fixed time. The progressive control tends towards a synchronization of signals CLK and REFCLK.

As a variation, comparator 14₁ directly transmits, over connection 20₁, an instruction of proportional or predetermined advance or delay to delay line 16₁ to create a local control loop.

Identical assemblies, sharing clock tree 12, are formed between circuits 6 and 8 and the other functions 2, 3, and 4. Such assemblies, each comprising a comparator 14 and a delay line 16, have been symbolized by blocks 30₂, 30₃, and 30₄. For simplification, the connections of blocks 30 to circuit 6 have not been shown, said connections being identical to those of the assembly of function 1.

An advantage of the described embodiments is that improving the synchronization of clock signals allows increasing the operating frequency.

Another advantage of the described embodiments is avoiding additional consumption power due to a uniform mesh layout.

Another advantage of the described embodiments is the ability to correct static and dynamic clock skews.

Another advantage of the described embodiments is the ability to decrease the power consumption by conditioning the activation of the calibration and of the de-skew to selected trigger thresholds.

Specific embodiments of the present invention have been described. Various alterations, modifications, and improvements will readily occur to those skilled in the art. It should be noted that those skilled in the art may combine various elements of these various embodiments and variations without showing any inventive step. In particular, the number of functions depends on the application. Further, the practical implementation of the described embodiments is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A circuit for detecting a time skew comprising:
at least two comparators;
a first set of paths respectively connecting a first source of a first signal to said comparators; and
a second set of paths respectively connecting a second source of a second signal to said comparators,
each comparator detecting a possible skew between said first and second signals.

2. The circuit of claim 1, comprising a delay block paired with each comparator.

3. The circuit of claim 1, wherein the first signal is a reference clock signal.

4. The circuit of claim 1, wherein the second signal is a useful clock signal.

5. The circuit of claim 1 wherein the circuit comprises a time skew circuit.

6. The circuit of claim 2, wherein each comparator forms, with the delay block associated therewith, a local control loop.

7. A circuit comprising:
a first clock generating circuit configured to generate a first clock signal;
a reference clock generating circuit configured to generate a reference clock signal;
a plurality of core circuits;
a first clock path configured to deliver the first clock signal;
a reference clock path configured to deliver the reference clock signal; and
a plurality of comparators, each comparator having a first input coupled to the first clock path, a second input coupled to the reference clock path, and an output coupled to a respective one of the plurality of core circuits, each comparator configured to compare a first clock signal received on the first clock path to a reference clock signal received on the reference clock path and to generate a skew signal.

8. The circuit of claim 7 further comprising:
a plurality of delay elements, each delay element coupled between the first clock generating circuit and a respective one of the plurality of core circuits, and configured to output to the respective one of the plurality of core circuits a delayed first clock signal, wherein the delayed clock signal is delayed be an amount proportionate to the skew signal.

9. The circuit of claim 8 further comprising a feedback loop comprising:
a first path between respective ones of the comparators and the reference clock generating circuit, the reference clock generating circuit, and a second path between the reference clock generating circuit and respective ones of the delay elements.

10. The circuit of claim 8 further comprising a feedback loop comprising:
a first path between respective ones of the comparators and respective ones of the delay elements.

11. The circuit of claim 8 wherein each delay element comprises a programmable delay line.

12. The circuit of claim 8 wherein the first clock path delivers the first clock signal to each of the plurality of core circuits via respective delay elements.

13. The circuit of claim 12 wherein the respective signal paths between the first clock signal generating circuit and the respective core circuits are substantially matched.

14. The circuit of claim 7 wherein respective ones of the plurality of core circuits operates synchronously.

15. The circuit of claim 7 wherein the first clock path is configured as a clock tree having a substantially identical layout between the first clock generating circuit and respective ones of the plurality of core circuits.

16. A method of synchronizing a circuit comprising:
generating a clock signal;
generating a reference clock signal;
delivering the clock signal and the reference clock signal to respective ones of a plurality of core circuits;
comparing, at said respective ones of the plurality of core circuits, the delivered clock signal and the delivered reference clock signal;
generating a plurality of skew signals in response to the comparing step, each skew signal being associated with the respective ones of the plurality of core circuits; and
delaying the respective clock signal delivered to the respective ones of the plurality of core circuits in response to respective ones of the plurality of skew signals, wherein one skew signal is generated for each respective one of the plurality of core circuits.

17. The method of claim 16 wherein delaying the respective clock signal comprises one of delaying the clock signal and advancing the clock signal.

18. The method of claim 16 further comprising feeding back the skew signal to a clock generator to form a feedback loop.

19. The method of claim 16 further comprising feeding back the skew signal to a local delay element to form a local feedback loop.

20. The method of claim 16 further comprising delivering the respective delayed clock signals to the respective ones of the plurality of core circuits.

21. The method of claim 16 wherein delaying the respective clock signal comprises generating no delay to the respective clock signal.
